(19) United States
(12) Patent Application Publication
(10) Pub. No.: US 2025/0087592 A1
(43) Pub. Date: Mar. 13, 2025

(54) PACKAGE STRUCTURE AND METHOD FOR FORMING THE SAME

(71) Applicant: Taiwan Semiconductor Manufacturing Company, Ltd., Hsinchu (TW)

(72) Inventors: Geng-Ming CHANG, Taichung City (TW); Kewei ZUO, Xinbei City (TW); Tzu-Cheng LIN, Hsinchu City (TW); Chih-Hang TUNG, Hsinchu (TW); Wen-Chih CHIOU, Miaoli County (TW); Wen-Yao CHANG, Hsinchu City (TW); Chen-Hua YU, Hsinchu City (TW)

(73) Assignee: Taiwan Semiconductor Manufacturing Company, Ltd., Hsinchu (TW)

(21) Appl. No.: 18/464,815

(22) Filed: Sep. 11, 2023

(51) Int. Cl. H01L 23/544; H01L 23/00; H01L 23/498; H01L 23/538; H01L 25/065

(52) U.S. Cl. CPC H01L 23/544; H01L 23/49816; H01L 23/5386; H01L 24/08; H01L 24/95; H01L 25/0652; H01L 2223/54426; H01L 2223/5448; H01L 2224/08245; H01L 2224/085; H01L 2224/95143; H01L 2924/13091

(57) ABSTRACT

A package structure includes a first bonding film on a first package component and a first alignment mark in the first bonding film. The first alignment mark includes a plurality of first patterns spaced apart from each other. The package structure includes a second bonding film on a second package component and bonded to the first bonding film, and a second alignment mark in the second bonding film. The second alignment mark includes a plurality of second patterns spaced apart from each other, and the first patterns overlap the second patterns. In this case, an interference pattern can be formed by the optical signal passing through the varying spacing between the gratings of top wafer and bottom wafer due to pitch difference between first pitch and second pitch. By reading the optical signal, the resolution of overlay (misalignment) measurement is improved.

### BACKGROUND

The semiconductor industry continues to improve the integration density of various electronic components (e.g., transistors, diodes, resistors, capacitors, etc.) by continual reductions in minimum feature size, which allow more components to be integrated into a given area. The individual dies are typically packaged separately. A package not only provides protection for semiconductor devices from environmental contaminants, but also provides a connection interface for the semiconductor devices packaged therein.

Three-dimensional integrated circuits (3DICs) are a recent development in semiconductor packaging in which multiple semiconductor dies are stacked upon one another, using package-on-package (POP) and system-in-package (SiP) packaging techniques. Some 3DICs are prepared by placing dies over dies on a semiconductor wafer level. 3DICs provide improved integration density and other advantages, such as faster speeds and higher bandwidth, because of the decreased length of interconnects between the stacked dies, for example. However, there are many challenges related to 3DICs.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIGS. 1A-1D are cross-sectional views illustrating various stages of forming a first alignment mark in accordance with some embodiments of the present disclosure.

FIG. 2A-2B are cross-sectional views illustrating various stages of forming a package structure in accordance with some embodiments of the present disclosure.

FIG. 3 is a cross-sectional view illustrating the package structure in accordance with some embodiments of the present disclosure.

FIG. 4A is a schematic top view illustrating the first alignment mark in accordance with some embodiments of the present disclosure.

FIG. 4B is a schematic top view illustrating the second alignment mark in accordance with some embodiments of the present disclosure.

FIG. 5 is a schematic top view illustrating the first alignment mark and the second alignment mark in accordance with some embodiments of the present disclosure.

FIG. 6A-6C are schematic top views illustrating the first alignment mark and the second alignment mark in accordance with some embodiments of the present disclosure.

FIG. 7A-7B are schematic top views illustrating the first alignment mark and the second alignment mark in accordance with some embodiments of the present disclosure.

FIG. 8A-8B are schematic top views illustrating the first alignment mark and the second alignment mark in accordance with some embodiments of the present disclosure.

FIG. 9 is a cross-sectional view illustrating the package structure in accordance with some embodiments of the present disclosure.

FIG. 10 is a cross-sectional view illustrating the package structure in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments of package structures and method for forming the same are provided. The package structure includes a first alignment mark and a second alignment mark corresponding to each other. Each of the first alignment mark and the second alignment mark includes a first group and a second group extending in two directions. Accordingly, the two-dimensional (2D) alignment may be achieved. In addition, a plurality of sub-alignment marks are provided in the first alignment mark and the second alignment mark, and therefore different resolution of may be obtained.

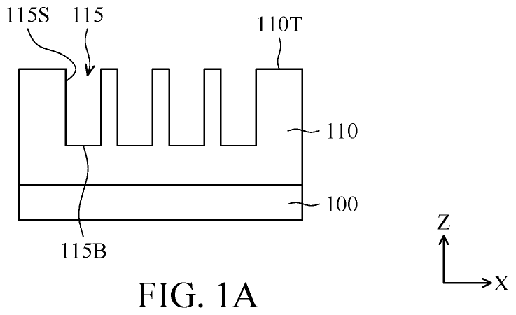

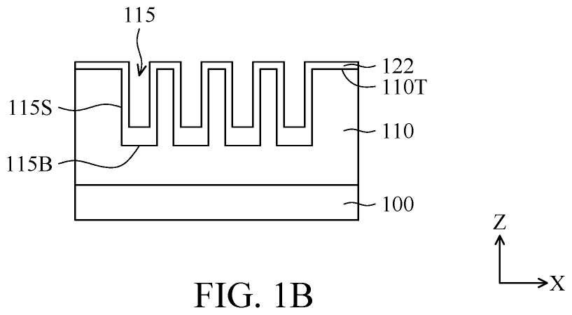

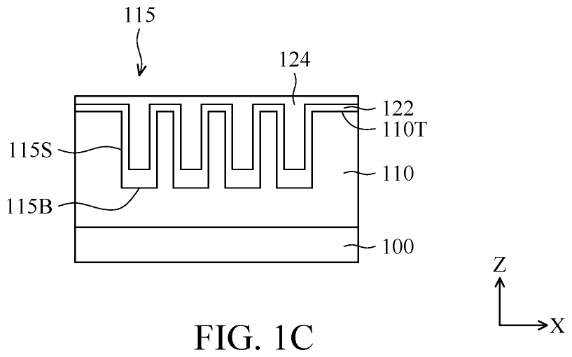

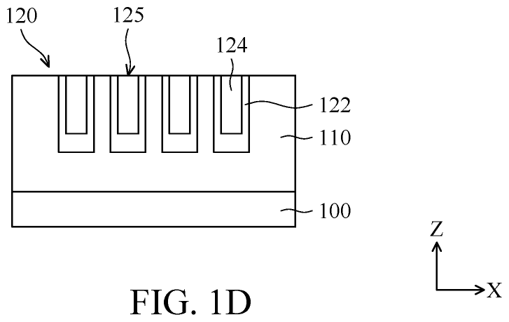

FIGS. 1A-1D are cross-sectional views illustrating various stages of forming a first alignment mark 120 in accordance with some embodiments of the present disclosure. For example, a first package component 100 includes a semiconductor substrate, including such as silicon, doped or undoped, or an active layer of a semiconductor-on-insulator (SOI) substrate. In some embodiments, the first package component 100 includes other semiconductor materials, such as germanium; a compound semiconductor including silicon carbide, gallium arsenic, gallium phosphide, indium phosphide, indium arsenide, and indium antimonide; an alloy semiconductor including SiGe, GaAsP, AlInAs, AlGaAs, GaInAs, GaInP, and GaInAsP; or a combination thereof. Other substrates, such as multi-layered or gradient substrates, may also be used.

In addition, a first bonding film 110 is formed over the first package component 100 for the subsequent bonding process. For example, the material of the first bonding film 110 includes SiON, SiO₂, any other suitable material, or a combination thereof. In some embodiments, a patterned photoresist layer (not shown) is formed over the first bonding film 110. The patterned photoresist layer may be formed by a deposition process and a patterning process. The deposition process for forming the patterned photoresist layer may include a chemical vapor deposition (CVD) process, a high-density plasma chemical vapor deposition (HDPCVD) process, a spin-on process, a sputtering process, or another applicable process. The patterning process for forming the patterned photoresist layer may include a photolithography process and an etching process. The photolithography process may include photoresist coating (e.g., spin-on coating), soft baking, mask aligning, exposure, post-exposure baking, developing the photoresist, rinsing, and drying (e.g., hard baking). The etching process may include a dry etching process or a wet etching process. Then, the first package component 100 may be recessed by performing an etching process, using the patterned photoresist layer as a mask, and a plurality of first trenches 115 are formed in the first bonding film 110. The etching process may be a dry etching process or a wet etching process. In some embodiments, the dry etching process includes using a fluorine-based etchant gas, such as SF₆, CₓF_{y}, NF₃ or a combination thereof. The etching process may be a time-controlled process. Afterwards, the patterned photoresist layer is removed.

In some embodiments, each of the first trenches 115 has a bottom surface 115B and a sidewall 115S that is connected to the bottom surface 115B. For example, the exemplary sidewall 115S is substantially perpendicular to the bottom surface 115B. However, the present disclosure is not limited thereto. The first trenches 115 are separated from each other by a part of the first bonding film 110. In some embodiments, the part of the first bonding film 110 is sandwiched between the adjacent first trenches 115 in a horizontal direction (for example, parallel to the X axis). In some embodiments, the depth of the first trenches 115 is less than the thickness of the first bonding film 110. That is, the first trenches 115 may not penetrate the first bonding film 110 and expose the underlying first package component 100. However, the present disclosure is not limited thereto. In some embodiments, the first trenches 115 are formed to have the same width in the direction parallel to the X-Y plane. In some embodiments, the first trenches 115 are formed with a constant interval. Accordingly, the spacing between the first trenches 115 is constant in the direction parallel to the X-Y plane. However, the present disclosure is not limited thereto.

Then, as shown in FIG. 1B, a first dielectric material 122 is deposited in the first trenches 115. In some embodiments, the first dielectric material 122 covers the bottom surface 115B and the sidewall 115S of the first trenches 115, and the top surface 110T of the first bonding film 110 is also covered by the first dielectric material 122. In some embodiments, the first dielectric material 122 is conformally formed on the first bonding film 110, but the present disclosure is not limited thereto. In some embodiments, the thickness of the first dielectric material 122 on the bottom surface 115B of the first trenches 115 is greater than and the thickness of the first dielectric material 122 on the sidewall 115S of the first trenches 115.

For example, the first dielectric material 122 includes one or more sub-dielectric layers formed of materials such as silicon dioxide (SiO₂), Phospho-Silicate Glass (PSG), Boro-Silicate Glass (BSG), Boron-Doped Phospho-Silicate Glass (BPSG), undoped Silicate Glass (USG), or the like. In some embodiments, the first dielectric material 122 is formed, for example, by spin coating, lamination, chemical vapor deposition (CVD), or the like. However, the present disclosure is not limited thereto. Any suitable material and method for the formation of the first dielectric material 122 is contemplated within the scope of the present disclosure.

As shown in FIG. 1C, a first conductive material 124 is deposited in the first trenches 115 and over the first dielectric material 122. For example, the first conductive material 124 include conductive material such as tungsten (W), cobalt (Co), nickel (Ni), copper (Cu), silver (Ag), gold (Au), aluminum (Al), any other suitable conductive material, or a combination thereof. In some embodiments, the first conductive material 124 and the first dielectric material 122 overfill the first trenches 115 and cover the top surface 110T of the first bonding film 110.

As shown in FIG. 1D, a planarization process (such as, chemical mechanical polish (CMP) or any other suitable planarization process) is performed on the first dielectric material 122 and the first conductive material 124. As a result, the top surfaces of the first dielectric material 122 and the first conductive material 124 may be substantially coplanar with the top surface 110T of the first bonding film 110. After the planarization process is completed, a first alignment mark 120 is formed in the first bonding film 110. The first alignment mark 120 includes a plurality of first patterns 125 that are spaced apart from each other. To be more specific, each of the first patterns 125 is formed by the first dielectric material 122 and the first conductive material 124 in each first trench 115. That is to say, the first dielectric material 122 and the first conductive material 124 in each of the first trenches 115 define each of the first patterns 125.

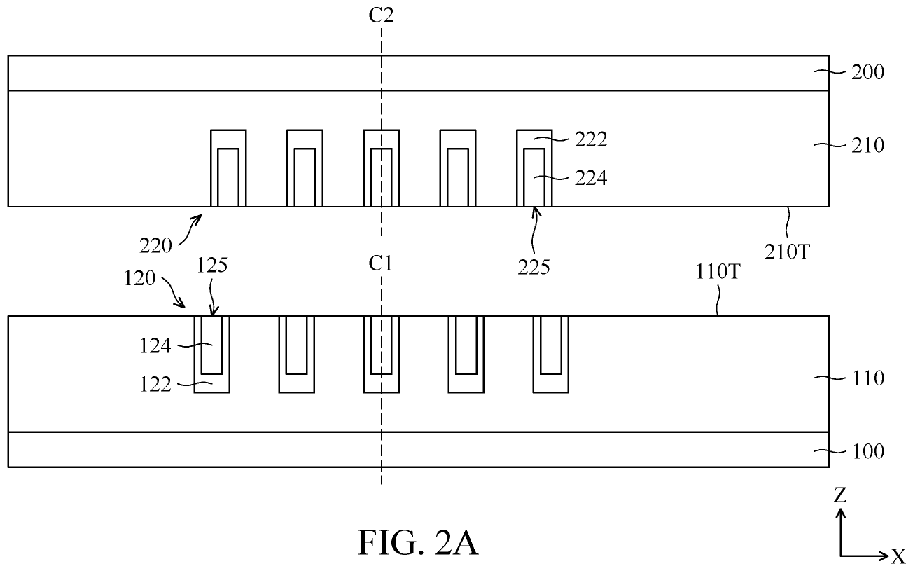

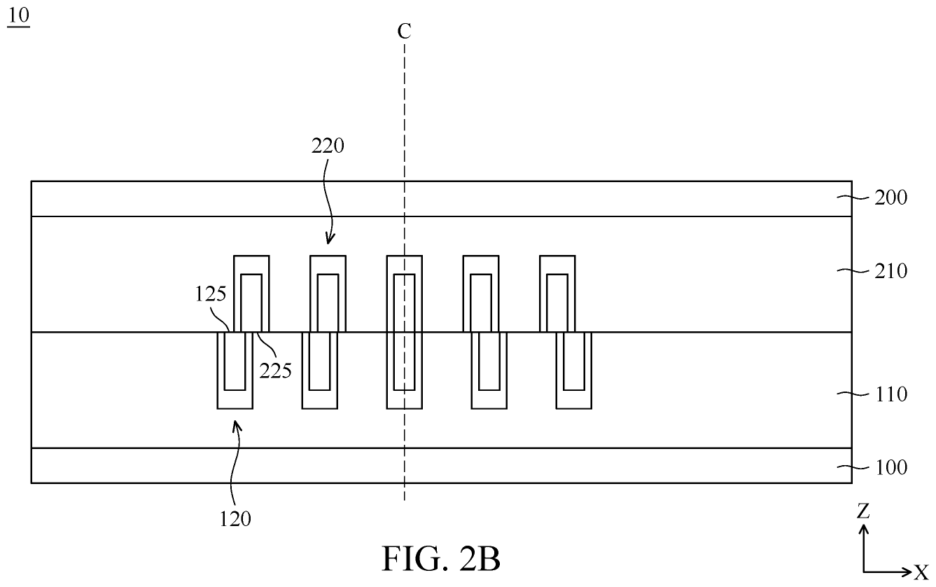

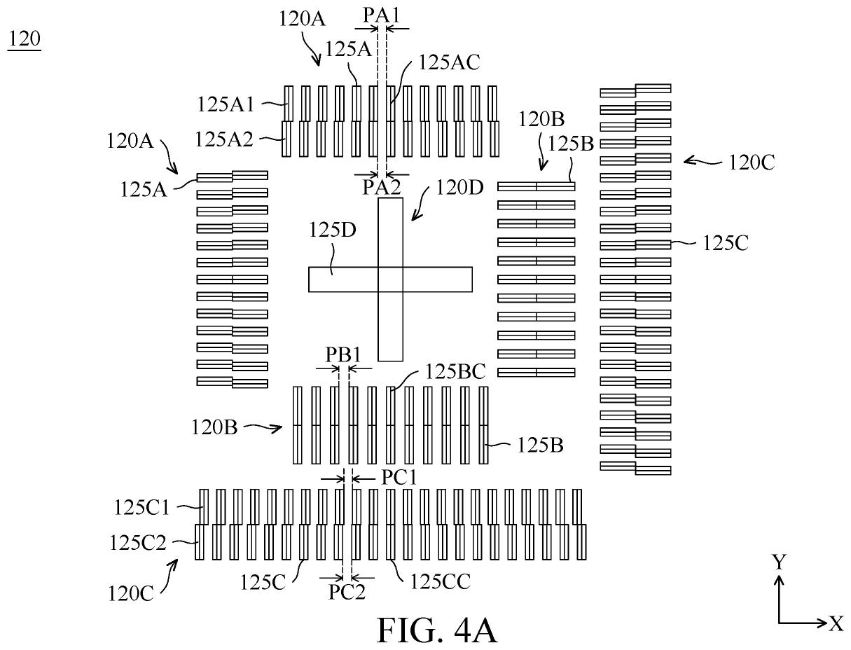

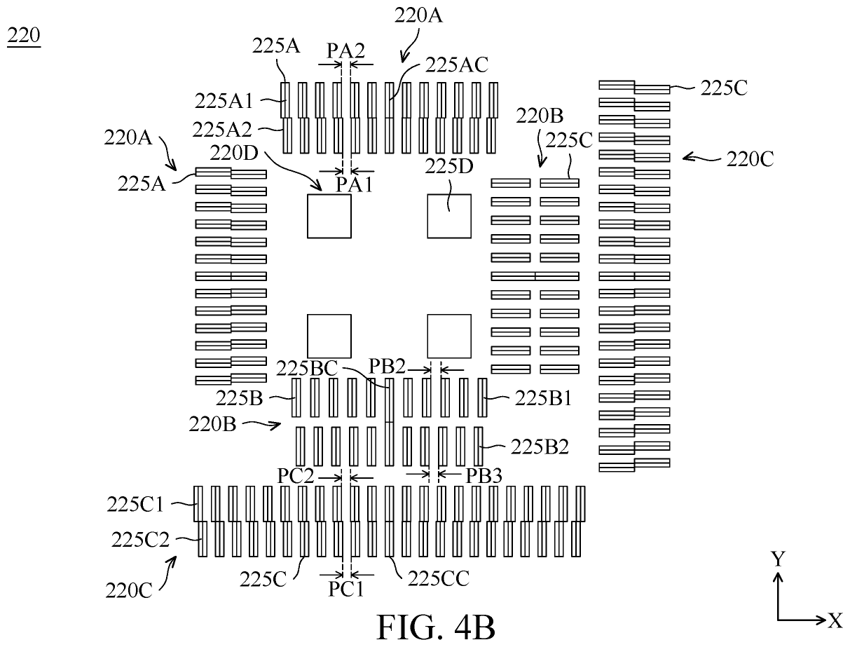

In some embodiments, the first alignment mark 120 may be formed by the first trenches 115, and the first dielectric material 122 and the first conductive material 124 may be omitted. The detail of the bonding process is further discussed in the following paragraphs in accompany with FIG. 2A-2B. The detail of the layout of the first alignment mark 120 is further discussed in the following paragraphs in accompany with FIG. 4A.

FIG. 2A-2B are cross-sectional views illustrating various stages of forming a package structure 10 in accordance with some embodiments of the present disclosure. In some embodiments, the package structure 10 is formed by bonding a second substrate 200 to the first package component 100. As shown in FIG. 2A, the first alignment mark 120 is formed in the first bonding film 110, which is located over the first package component 100. In addition, a second alignment mark 220 is formed in a second bonding film 210, which is located over the second substrate 200. In some embodiments, the second alignment mark 220 is formed in the second bonding film 210 using the material of method that is the same as that of the first alignment mark 120. For example, a second dielectric material 222 and a second conductive material 224 are filled into a plurality of second trenches 215 in the second bonding film 210. Then, a planarization process performed on the second bonding film 210, and the second alignment mark 220 is formed and includes a plurality of second patterns 225 that are spaced apart from each other. To be more specific, each of the second patterns 225 is formed by the second dielectric material 222 and the second conductive material 224 in each second trench 215. That is to say, the second dielectric material 222 and the second conductive material 224 in each of the second trenches 215 define each of the second patterns 225. The detail of the layout of the second alignment mark 220 is further discussed in the following paragraphs in accompany with FIG. 4B.

In some embodiments, the first alignment mark 120 has a first axis C1, and the second alignment mark 220 has a second axis C2. To be more specific, the first axis C1 is perpendicular to the top surface 110T of the first bonding film 110. Similarly, the second axis C2 is perpendicular to the top surface 210T of the second bonding film 210. As shown in FIG. 2A, before the second substrate 200 is bonded to the first package component 100, the first axis C1 of the first alignment mark 120 is aligned with the second axis C2 of the second alignment mark 220. Then, as shown in FIG. 2B, after it is determined that the first axis C1 of the first alignment mark 120 is coincident with the second axis C2 of the second alignment mark 220, the second substrate 200 is moved towards the first package component 100, and the first bonding film 110 is combined with (for example, in contact with) the second bonding film 210. In the present embodiment, the first axis C1 and the second axis C2 are integrated together as the aligned axis C. In some embodiments, the first alignment mark 120 at least partially overlaps the second alignment mark 220 in a vertical direction (which is, for example, parallel to the aligned axis C). With the arrangement of the first alignment mark 120 and the second alignment mark 220, the process time and cost for bonding the first package component 100 and the second substrate 200 may be reduced.

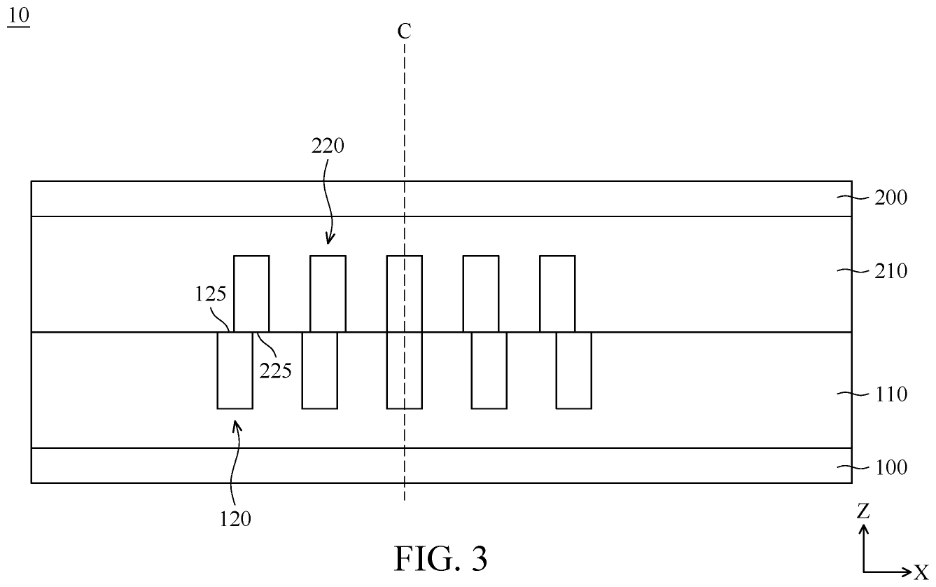

FIG. 3 is a cross-sectional view illustrating the package structure 10 in accordance with some embodiments of the present disclosure. It should be noted that the package structure 10 shown in the present embodiment includes components or portions which are the same or similar to those of the package structure 10 shown in FIG. 2B. These components or portions will be denoted as the same or similar numerals, and will not be discussed in detail in the following paragraphs. For example, as shown in FIG. 3, the package structure 10 in includes the first substrate 100 and the second substrate 200 which are bonded to each other via the first bonding film 110 and the second bonding film 220. The difference between the embodiment shown in FIG. 3 and the embodiment shown in FIG. 2B is that the first patterns 125 and the second patterns 225 are formed without the first dielectric material 122 and the first conductive material 124 (or the second dielectric material 222 and the second conductive material 224). That is to say, the first patterns 125 and the second patterns 225 may be formed by empty trenches (for example, the first trenches 115 or the second trenches 215). However, the present disclosure is not limited thereto.

FIG. 4A is a schematic top view illustrating the first alignment mark 120 in accordance with some embodiments of the present disclosure. As shown in FIG. 4A, the first alignment mark 120 includes a plurality of sub-alignment marks 120A, 120B, 120C, and 120D, which includes a group of first patterns 125A, 125B, 125C, and 125D, respectively. In some embodiments, for the sake of clarity, the sub-alignment mark 120A may be referred to as “first sub-alignment mark 120A.” Similarly, the sub-alignment mark 120B may be referred to as “second sub-alignment mark 120B,” the sub-alignment mark 120C may be referred to as “third sub-alignment mark 120C,” and the sub-alignment mark 120D may be referred to as “fourth sub-alignment mark 120D.” It should be noted that these ordinal numbers are provided for distinguishing from each other without indicating the priority or relationship among these sub-alignment marks. In some embodiments, the sub-alignment marks 120A, 120B, 120C, and 120D may exist and function independently, as long as their corresponding sub-alignment marks 220A, 220B, 220C and 220D (which will be described in the following paragraphs in accompany with FIG. 4B) are present. For example, the first alignment mark 120 includes each of the sub-alignment marks 120A, 120B, 120C, and 120D. In some embodiments, the first alignment mark 120 may merely include the sub-alignment mark 120C. However, the present disclosure is not limited thereto.

In some embodiments, in the top view (for example, shown in FIG. 4A), the first sub-alignment mark 120A of the first alignment mark 120 includes a plurality of first patterns 125A. For example, the first group of the first patterns 125A are arranged in the first direction (parallel to the X axis, for example), and the second group of the first patterns 125A are arranged in the second direction (parallel to the Y axis, for example). The second direction is substantially perpendicular to the first direction. Accordingly, the first alignment mark 120 may be used to align two components of the package structure in two dimensions.

In addition, each of the first patterns 125A is divided into a first portion 125A1 and a second portion 125A2 connected to the first portion 125A1. However, the present disclosure is not limited thereto. In some embodiments, the first portions 125A1 of the first patterns 125A may be disconnected from the second portions 125A2 of the first patterns 125A. For example, the width of the first portions 125A1 and/or the second portions 125A2 is in a range from about 0.1 μm to about 10 μm, but the present disclosure is not limited thereto. The first portions 125A1 of the first patterns 125A are separated by a first pitch PA1. The second portions 125A2 of the first patterns 125A are separated by a second pitch PA2. The first pitch PA1 is different from the second pitch PA2. In some embodiments, a standard pattern 125AC is selected in the first group of the first patterns 125A. To be more specific, the standard pattern 125AC includes a first portion 125A1 and a second portion 125A2 that are aligned with each other in the second direction (such as the direction parallel to the Y axis). That is to say, one of the edges of the first portion 125A1 and a corresponding one of the edges of the second portion 125A2 form a straight line in the standard pattern 125AC.

In some embodiments, in the top view (for example, shown in FIG. 4A), the first group of the first patterns 125A are arranged symmetrically about a central axis. For example, the first patterns 125A are symmetrically arranged on opposite sides of the standard pattern 125AC. In some embodiments, in the top view (for example, shown in FIG. 4A), the first portions 125A1 and the second portions 125A2 of the first patterns 125A each have an elongated shape, such as rectangle. However, the present disclosure is not limited thereto. Other regular or irregular shapes of the first patterns 125A are still possible and included within the scope of the present disclosure.

In the present embodiment, the first pitch PA1 is in a range from about 0.1 μm to about 10 μm, such as about 2.0 μm. In addition, and the second pitch PA2 is in a range from about 0.1 μm to about 10 μm, such as about 2.1 μm. In some embodiments, the first pitch PA1 is different from (for example, shorter than) the second pitch PA2. In some embodiments, the difference between the first pitch PA1 and the second pitch PA2 is, for example, about 0.1 μm. However, the present disclosure is not limited thereto. Other possible values of the difference between the first pitch PA1 and the second pitch PA2 are included within the scope of the present disclosure and will not be listed one-by-one below. For example, the first pitch PA1 and the second pitch PA2 are interchangeable, so that in some embodiments the first pitch PA1 may be greater than the second pitch PA2. It should be noted that the difference between the first pitch PA1 and the second pitch PA2 may determine the resolution of the misalignment error (for example, the shift between the first alignment mark 120 and the second alignment mark 220). The determination of a misalignment error is discussed further in the following paragraphs.

In some embodiments, the second sub-alignment mark 120B of the first alignment mark 120 includes a plurality of first patterns 125B. It should be noted that although the first patterns 125B are each illustrated as a one-piece structure in the present embodiment, the present disclosure is not limited thereto. That is the first patterns 125B may include a first portion and a second portion that are disconnected from each other. For example, the width of the first patterns 125B is in a range from about 0.1 μm to about 10 μm, but the present disclosure is not limited thereto. For example, a first group of the first patterns 125B are arranged in the first direction (such as a direction parallel to the X axis), and a second group of the first patterns 125B are arranged in a second direction (such as the direction parallel to the Y axis) that is substantially perpendicular to the first direction. Accordingly, the first alignment mark 120 may be used to align two components of the package structure in two dimensions.

In addition, the first patterns 125B are separated by a first pitch PB1. In some embodiments, a standard pattern 125BC is selected in the first group of the first patterns 125B. In some embodiments, in the top view (for example, shown in FIG. 4A), the first group of the first patterns 125B are arranged symmetrically about the first axis (for example, parallel to the Y axis). For example, the first patterns 125B are symmetrically arranged on opposite sides of the standard pattern 125BC. In some embodiments, in the top view (for example, shown in FIG. 4A), the first patterns 125B each have an elongated shape, such as rectangle. For example, the first patterns 125B have the shape of a rectangle with a uniform length. However, the present disclosure is not limited thereto. Other regular or irregular shapes of the first patterns 125B are still possible and included within the scope of the present disclosure. In some embodiments, in the top view (for example, shown in FIG. 4A), the first patterns 125B are identical to each other. In the present embodiment, the first pitch PB1 is in a range from about 0.1 μm to about 10 μm, such as about 2.2 μm.

In some embodiments, the third sub-alignment mark 120C of the first alignment mark 120 includes a plurality of first patterns 125C. For example, a first group of the first patterns 125C are arranged in the first direction (such as a direction parallel to the X axis), and a second group of the first patterns 125C are arranged in a second direction (such as a direction parallel to the Y axis) that is substantially perpendicular to the first direction. Accordingly, the first alignment mark 120 may be used to align two components of the package structure in two dimensions.

In addition, each of the first patterns 125C is divided into a first portion 125C1 and a second portion 125C2 connected to the first portion 125C1. However, the present disclosure is not limited thereto. In some embodiments, the first portions 125C1 of the first patterns 125C may be disconnected from the second portions 125C2 of the first patterns 125C. For example, the width of the first portions 125C1 and/or the second portions 125C2 is in a range from about 0.1 μm to about 10 μm, but the present disclosure is not limited thereto. The first portions 125C1 of the first patterns 125C are separated by a first pitch PC1. The second portions 125C2 of the first patterns 125C are separated by a second pitch PC2. The first pitch PC1 is different from the second pitch PC2. In some embodiments, a standard pattern 125CC is selected in the first group of the first patterns 125C. To be more specific, the standard pattern 125CC includes a first portion 125C1 and a second portion 125C2 that are aligned with each other in the second direction (such as the direction parallel to the Y axis). That is to say, one of the edges of the first portion 125C1 and a corresponding one of the edges of the second portion 125C2 form a straight line in the standard pattern 125CC.

In some embodiments, in the top view (for example, shown in FIG. 4A), the first group of the first patterns 125C are arranged symmetrically about a central axis. For example, the first patterns 125C are symmetrically arranged on opposite sides of the standard pattern 125CC. In some embodiments, in the top view (for example, shown in FIG. 4A), the first portions 125C1 and the second portions 125C2 of the first patterns 125C each have an elongated shape, such as rectangle. However, the present disclosure is not limited thereto. Other regular or irregular shapes of the first patterns 125C are still possible and included within the scope of the present disclosure.

In the present embodiment, the first pitch PC1 is in a range from about 0.1 μm to about 10 μm, such as about 2.0 μm. In addition, and the second pitch PC2 is in a range from about 0.1 μm to about 10 μm, such as about 2.02 μm. In some embodiments, the first pitch PC1 is different from (for example, shorter than) the second pitch PC2. In some embodiments, the difference between the first pitch PC1 and the second pitch PC2 is, for example, about 0.02 μm. However, the present disclosure is not limited thereto. Other possible values of the difference between the first pitch PC1 and the second pitch PC2 are included within the scope of the present disclosure and will not be listed one-by-one below. For example, the first pitch PC1 and the second pitch PC2 are interchangeable, so that in some embodiments the first pitch PC1 may be greater than the second pitch PC2.

It should be noted that the difference between the first pitch PC1 and the second pitch PC2 may determine the resolution of the misalignment error (for example, the shift between the first alignment mark 120 and the second alignment mark 220). In particular, compared with the first pitch PA1 and the second pitch PA2, the first pitch PC1 and the second pitch PC2 are shorter and may achieve higher resolution of the misalignment error. The determination of a misalignment error is discussed further in the following paragraphs.

In some embodiments, the fourth sub-alignment mark 120D of the first alignment mark 120 includes a first pattern 125D, which has a cross profile in the top view (for example, shown in FIG. 4A). However, the present disclosure is not limited thereto. Other regular or irregular shapes of the first pattern 125D are still possible and included within the scope of the present disclosure. In some other embodiments, the fourth sub-alignment mark 120D of the first alignment mark 120 may include a plurality of first patterns 125D that are spaced from each other.

FIG. 4B is a schematic top view illustrating the second alignment mark 220 in accordance with some embodiments of the present disclosure. As shown in FIG. 4B, the second alignment mark 220 includes a plurality of sub-alignment marks 220A, 220B, 220C, and 220D, which includes a group of second patterns 225A, 225B, 225C, and 225D, respectively. In some embodiments, for the sake of clarity, the sub-alignment mark 220A may be referred to as “first sub-alignment mark 220A.” Similarly, the sub-alignment mark 220B may be referred to as “second sub-alignment mark 220B,” the sub-alignment mark 220C may be referred to as “third sub-alignment mark 220C,” and the sub-alignment mark 220D may be referred to as “fourth sub-alignment mark 220D.” It should be noted that these ordinal numbers are provided for distinguishing from each other without indicating the priority or relationship among these sub-alignment marks. In some embodiments, the sub-alignment marks 220A, 220B, 220C, and 220D may exist and function independently, as long as their corresponding sub-alignment marks 120A, 120B, 120C and 120D (which were described as above in accompany with FIG. 4A) are present. For example, the second alignment mark 220 includes each of the sub-alignment marks 220A, 220B, 220C, and 220D. In some embodiments, the second alignment mark 220 may merely include the sub-alignment mark 220C. However, the present disclosure is not limited thereto.

In some embodiments, in the top view (for example, shown in FIG. 4B), the first sub-alignment mark 220A of the second alignment mark 220 includes a plurality of second patterns 225A. For example, a first group of the second patterns 225A are arranged in the first direction (such as a direction parallel to the X axis), and a second group of the second patterns 225A are arranged in the second direction (such as a direction parallel to the Y axis) that is substantially perpendicular to the first direction. Accordingly, the second alignment mark 220 may be used to align two components of the package structure in two dimensions and correspond to the first alignment mark 120.

In addition, each of the second patterns 225A is divided into a first portion 225A1 and a second portion 225A2 connected to the first portion 225A1. However, the present disclosure is not limited thereto. In some embodiments, the first portions 225A1 of the second patterns 225A may be disconnected from the second portions 225A2 of the second patterns 225A. For example, the width of the first portions 225A1 and/or the second portions 225A2 is in a range from about 0.1 μm to about 10 μm, but the present disclosure is not limited thereto. The first portions 225A1 of the second patterns 225A are separated by the second pitch PA2. The second portions 225A2 of the second patterns 225A are separated by the first pitch PA1. In some embodiments, a standard pattern 225AC is selected in the first group of the second patterns 225A. To be more specific, the standard pattern 225AC includes a first portion 225A1 and a second portion 225A2 that are aligned with each other in the second direction (such as the direction parallel to the Y axis). That is to say, one of the edges of the first portion 225A1 and a corresponding one of the edges of the second portion 225A2 form a straight line in the standard pattern 225AC.

In some embodiments, in the top view (for example, shown in FIG. 4B), the first group of the second patterns 225A are arranged symmetrically about a central axis. For example, the second patterns 225A are symmetrically arranged on opposite sides of the standard pattern 225AC. In some embodiments, in the top view (for example, shown in FIG. 4B), the first portions 225A1 and the second portions 225A2 of the second patterns 225A each have an elongated shape, such as rectangle. However, the present disclosure is not limited thereto. Other regular or irregular shapes of the first patterns 225A are still possible and included within the scope of the present disclosure.

In some embodiments, the second sub-alignment mark 220B of the second alignment mark 220 includes a plurality of second patterns 225B. For example, a first group of the second patterns 225B are arranged in the first direction (such as a direction parallel to the X axis), and a second group of the second patterns 225B are arranged in a second direction (such as the direction parallel to the Y axis) that is substantially perpendicular to the first direction. Accordingly, the second alignment mark 220 may be used to align two components of the package structure in two dimensions and correspond to the first alignment mark 120.

In addition, the second patterns 225B each include a first portion 225B1 and a second portion 225B2. For example, the width of the first portions 225B1 and/or the second portions 225B2 is in a range from about 0.1 μm to about 10 μm, but the present disclosure is not limited thereto. In some embodiments, the first portions 225B1 of the second patterns 225B are separated by a second pitch PB2, and the second portions 225B2 of the second patterns 225B are separated by a third pitch PB3. In some embodiments, the second pitch PB2 is different from the third pitch PB3. In the present embodiment, the second pitch PB2 is in a range from about 0.1 μm to about 10 μm, such as about 2.1 μm. The third pitch PB3 is in a range from about 0.1 μm to about 10 μm, such as about 2.0 μm. For example, the relationship among the first pitch PB1, the second pitch PB2, and the third pitch PB3 are reversable, so that in some embodiments the first pitch PC1 may be shorter than the second pitch PB2 and/or the third pitch PB3. In some embodiments, a standard pattern 225BC is selected in the first group of the second patterns 225B. In some embodiments, in the top view (for example, shown in FIG. 4B), the first group of the second patterns 225B are arranged symmetrically about the first axis (for example, parallel to the Y axis). For example, the second patterns 225B are symmetrically arranged on opposite sides of the standard pattern 225BC. In some embodiments, the first portion 225B1 and the second portion 225B2 of the standard pattern 225BC are connected to each other for the ease of observation. In some embodiments, in the top view (for example, shown in FIG. 4B), the first portions 225B1 and/or the second portions 225B2 of the second patterns 225B each have an elongated shape, such as rectangle. However, the present disclosure is not limited thereto. Other regular or irregular shapes of the second patterns 225B are still possible and included within the scope of the present disclosure.

In some embodiments, the third sub-alignment mark 220C of the second alignment mark 220 includes a plurality of second patterns 225C. For example, a first group of the second patterns 225C are arranged in the first direction (such as a direction parallel to the X axis), and a second group of the second patterns 225C are arranged in a second direction (such as a direction parallel to the Y axis) that is substantially perpendicular to the first direction. Accordingly, the second alignment mark 220 may be used to align two components of the package structure in two dimensions and correspond to the first alignment mark 120.

In addition, each of the second patterns 225C is divided into a first portion 225C1 and a second portion 225C2 connected to the first portion 225C1. However, the present disclosure is not limited thereto. In some embodiments, the first portions 225C1 of the second patterns 225C may be disconnected from the second portions 225C2 of the second patterns 225C. For example, the width of the first portions 225C1 and/or the second portions 225C2 is in a range from about 0.1 μm to about 10 μm, but the present disclosure is not limited thereto. The first portions 225C1 of the second patterns 225C are separated by the second pitch PC2. The second portions 225C2 of the second patterns 225C are separated by the first pitch PC1. In some embodiments, a standard pattern 225CC is selected in the first group of the second patterns 225C. To be more specific, the standard pattern 225CC includes a first portion 225C1 and a second portion 225C2 that are aligned with each other in the second direction (such as the direction parallel to the Y axis). That is to say, one of the edges of the first portion 225C1 and a corresponding one of the edges of the second portion 225C2 form a straight line in the standard pattern 225CC.

In some embodiments, in the top view (for example, shown in FIG. 4B), the first group of the second patterns 225C are arranged symmetrically about a central axis. For example, the second patterns 225C are symmetrically arranged on opposite sides of the standard pattern 225CC. In some embodiments, in the top view (for example, shown in FIG. 4A), the first portions 225C1 and the second portions 225C2 of the second patterns 225C each have an elongated shape, such as rectangle. However, the present disclosure is not limited thereto. Other regular or irregular shapes of the second patterns 225C are still possible and included within the scope of the present disclosure.

In some embodiments, the fourth sub-alignment mark 220D of the second alignment mark 220 includes a plurality of second pattern 225D, each of which has a rectangular profile in the top view (for example, shown in FIG. 4A). However, the present disclosure is not limited thereto. Other regular or irregular shapes of the second pattern 225D are still possible and included within the scope of the present disclosure.

Although the detail structures of the first alignment mark 120 and the second alignment mark 220 are discussed above, the present disclosure is not limited thereto. It should be noted that the structures of the first alignment mark 120 and the second alignment mark 220 are interchangeable. For example, the second alignment mark 220 may be formed at the top of the overall package structure 10 and the first alignment mark 120 may be formed at the bottom of the overall package structure 10.

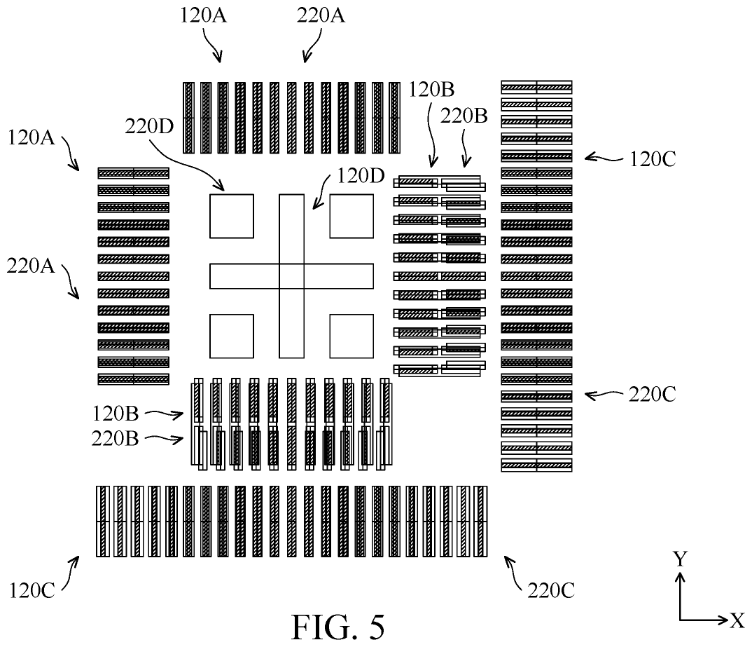

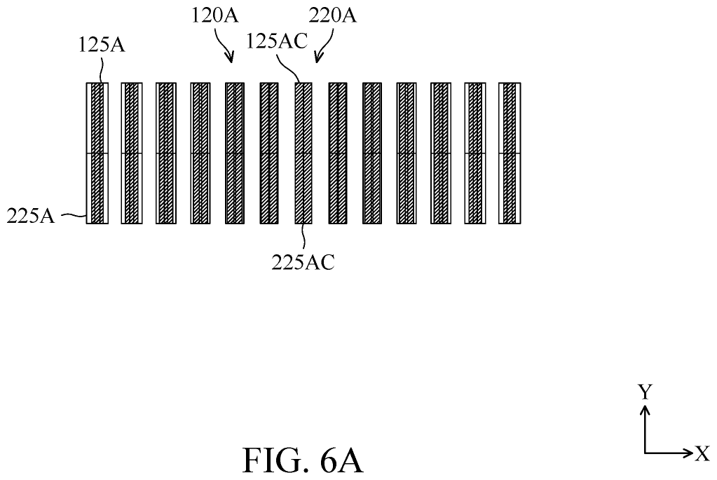

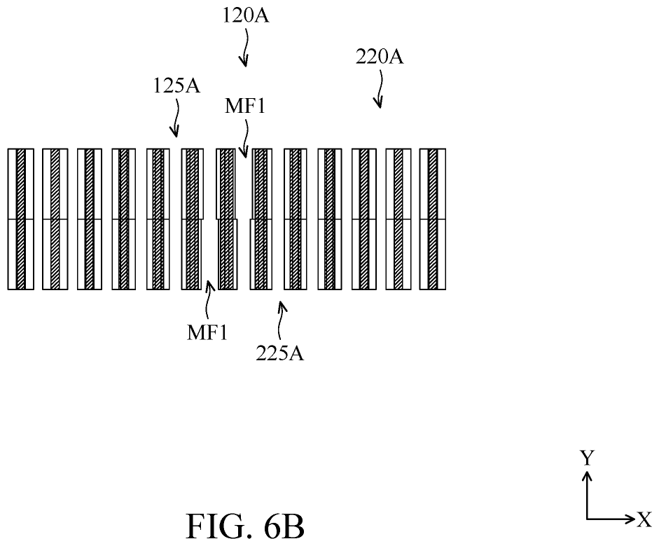

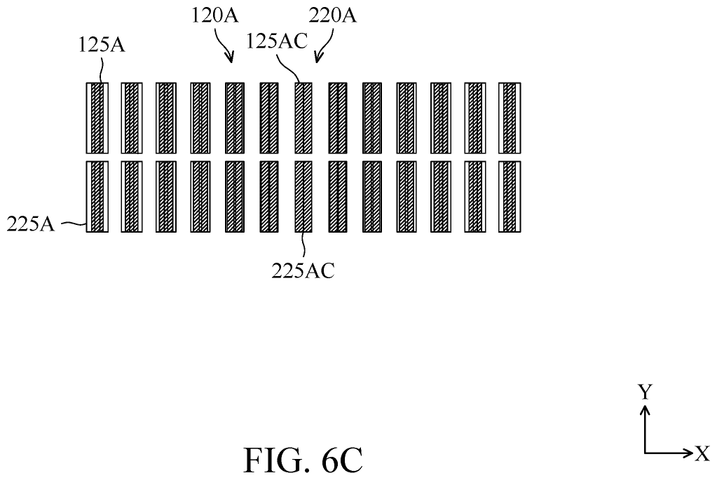

FIG. 5 is a schematic top view illustrating the first alignment mark 120 and the second alignment mark 220 in accordance with some embodiments of the present disclosure. As shown in FIG. 5, the first alignment mark 120 is aligned with and overlap the second alignment mark 220. To be more specific, the first sub-alignment mark 120A of the first alignment mark 120 is aligned with and at least partially overlaps the first sub-alignment mark 220A of the second alignment mark 220. Similarly, the second sub-alignment mark 120B of the first alignment mark 120 is aligned with and at least partially overlaps the second sub-alignment mark 220B of the second alignment mark 220. The third sub-alignment mark 120C of the first alignment mark 120 is aligned with and at least partially overlaps the third sub-alignment mark 220C of the second alignment mark 220. In addition, the fourth sub-alignment mark 120D of the first alignment mark 120 is aligned with and spaced apart from the second sub-alignment mark 220B of the second alignment mark 220 in the top view. The detail of the alignment between the first alignment mark 120 and the second alignment mark 220 will be further discussed with respect to FIG. 6A through FIG. 8B.

As set forth above, various alignment marks are provided. It should be noted that it may not be necessary to include all kinds of alignment marks which are discussed above, one or more alignment marks described in the present disclosure may be selected for alignment of the package structure 10.

FIG. 6A-6C are schematic top views illustrating the first alignment mark 120 and the second alignment mark 220 in accordance with some embodiments of the present disclosure. As shown in FIG. 6A, the first sub-alignment mark 120A of the first alignment mark 120 is aligned with the first sub-alignment mark 220A of the second alignment mark 220. To be more specific, the standard pattern 125AC of the first sub-alignment mark 120A is substantially coincident with the standard pattern 220AC of the first sub-alignment mark 220A. In the top view (for example, shown in FIG. 5A), a corresponding pair of the first patterns 125A and the second patterns 225A may have a rectangular profile. To be more specific, the first portions 125A1 of the first patterns 125A overlap the first portions 225A1 of the second patterns 225A, and the second portions 125A2 of the first patterns 125A overlap the second portions 225A2 of the second patterns 225A.

As shown in FIG. 6B, when the first sub-alignment mark 120A of the first alignment mark 120 is misaligned with the first sub-alignment mark 220A of the second alignment mark 220, a pair of misalignment features MF1 may be observed on opposite sides of the first sub-alignment mark 120A (and the first sub-alignment mark 220A). In particular, the misalignment features MF1 may be identified as an interference pattern formed by the optical signal passing through the varying spacing between the alignment marks 120 and 220 on the substrates 100 and 200. As a result, the misalignment error may be determined based on the location of the misalignment features MF1 and the pitch difference between the first patterns 125A and the second pattern 225A. For example, the resolution of the misalignment error may be about 50 nm, but the present disclosure is not limited thereto. To be more specific, the resolution of the misalignment error may be determined as the pitch difference between the pitch PA1 and the pitch PA2. In some embodiments, the resolution of the misalignment error may be in a range from about 1 nm to about 200 nm. Then, the misalignment error may be determined by the following formula:

The misalignment error=The resolution*The inversion point of light signal

In some embodiments, the inversion point of light signal may be identified as the two elongated patterns that are most aligned and have the widest spacing therebetween. Accordingly, the misalignment error may be obtained rapidly and the risk of miscalculating the misalignment error may be reduced.

In some embodiments, the misalignment error may be determined by identifying the centers of the first sub-alignment mark 120A and the first sub-alignment mark 220A and calculating the overlay (or misalignment) between the centers of the first sub-alignment mark 120A and the first sub-alignment mark 220A. In particular, the center of the first sub-alignment mark 120A may be identified by averaging the position of the centers of the first patterns 125A. For example, thirteen first patterns 125A are shown in this embodiment, and the positions of the centers of these first patterns 125A are averaged to obtain the averaged center of the first sub-alignment mark 120A. Similarly, the averaged center of the first sub-alignment mark 220A may be obtained in the same manner.

In some embodiments, the misalignment error may be determined by the following formula:

The misalignment error=The number of the first patterns 125A or the second patterns 225A*Pitch Difference between the first patterns 125A and the second pattern 225A (i.e. the pitch difference between the pitch PA1 and the pitch PA2)−Pitch Difference/2

Accordingly, the misalignment error may be obtained rapidly and the risk of miscalculating the misalignment error may be reduced. In some embodiments, the number of the first patterns 125A or the second patterns 225A in a range from 10 to 100 on each side.

As shown in FIG. 6C, the first portions 125A1 of the first patterns 125A may be disconnected from the second portions 125A2 of the first patterns 125A. Similarly, the first portions 225A1 of the second patterns 225A may be disconnected from the second portions 225A2 of the second patterns 225A. As a result, the design of the first patterns 125A and the second patterns 225A may vary without degrading the resolution of the misalignment error.

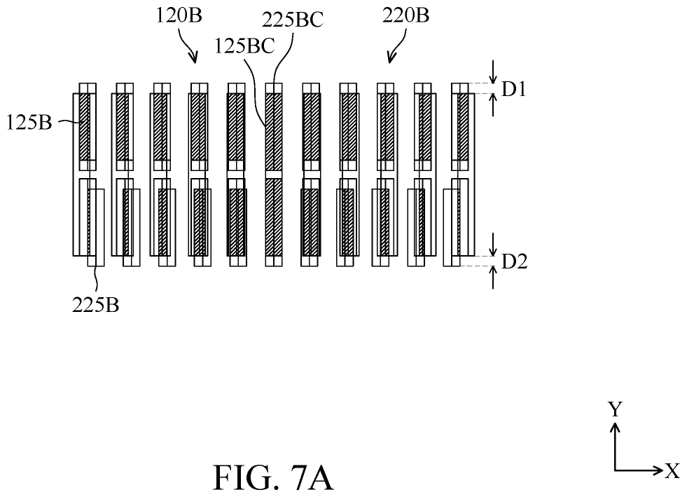

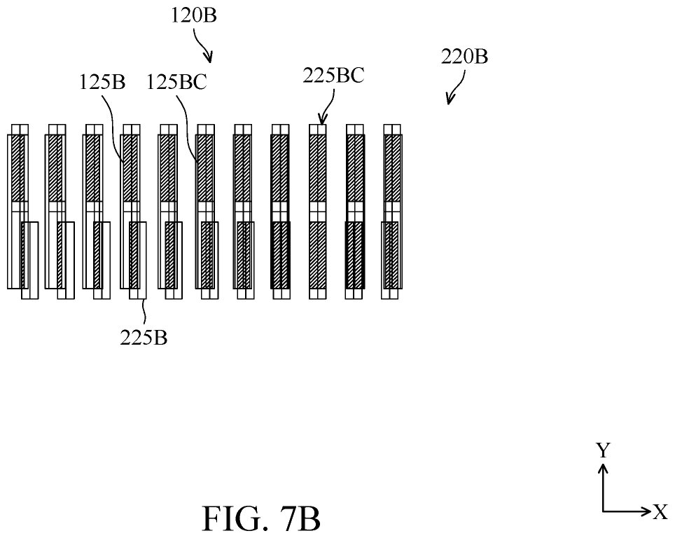

FIG. 7A-7B are schematic top views illustrating the first alignment mark 120 and the second alignment mark 220 in accordance with some embodiments of the present disclosure. As shown in FIG. 7A, the second sub-alignment mark 120B of the first alignment mark 120 is aligned with the second sub-alignment mark 220B of the second alignment mark 220. To be more specific, the standard pattern 125BC of the second sub-alignment mark 120B is substantially coincident with the standard pattern 220BC of the second sub-alignment mark 220B. In some embodiments, a length of the standard pattern 125BC of the first patterns 125B is different from a length of the standard pattern 225BC of the second patterns 225B in a direction (e.g. the Y direction) parallel to the edges of the standard pattern 125BC of the first patterns 125B. For example, the length of the first patterns 125B is different from (for example, greater than or shorter than) the length of the second patterns 225B in the Y direction. In some embodiments, the height differences D1 and D2 between the first patterns 125B and the second patterns 225B are each in a range from about 0.1 μm to about 10 μm, but the present disclosure is not limited thereto. In some embodiments, the height differences D1 and D2 may also exist between the first patterns 125A and the second patterns 225A, or between the first patterns 125C and the second patterns 225C. The height differences D1 and D2 may help to identify the first alignment mark 120 and the second alignment mark 220, reducing the risk of misalignment.

As shown in FIG. 7B, the second sub-alignment mark 120B of the first alignment mark 120 is misaligned with the second sub-alignment mark 220B of the second alignment mark 220. However, the misalignment error may be determined based on the locations of the standard patterns 120BC and 220BC along with the pitch difference between the first patterns 125B and the second pattern 225B. For example, the resolution of the misalignment error may be in a range from about 100 nm to about 200 nm, but the present disclosure is not limited thereto. To be more specific, the resolution of the misalignment error may be determined as the pitch difference between the pitch PB1 and the pitch PB2 (or the pitch difference between the pitch PB1 and the pitch PB3). That is, multiple resolutions may be obtained from the first patterns 125B and the second pattern 225B. In some embodiments, the resolution of the misalignment error may be in a range from about 1 nm to about 200 nm. Then, the misalignment error may be determined by the following formula:

The misalignment error=The resolution*The inversion point of light signal

In some embodiments, the inversion point of light signal may be identified as the two elongated patterns that are most aligned and have the widest spacing therebetween. Accordingly, the misalignment error may be obtained rapidly and the risk of miscalculating the misalignment error may be reduced.

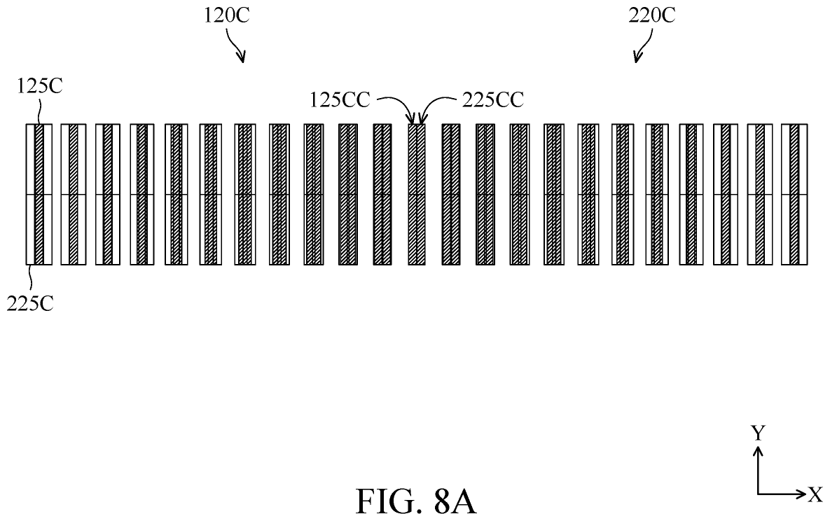

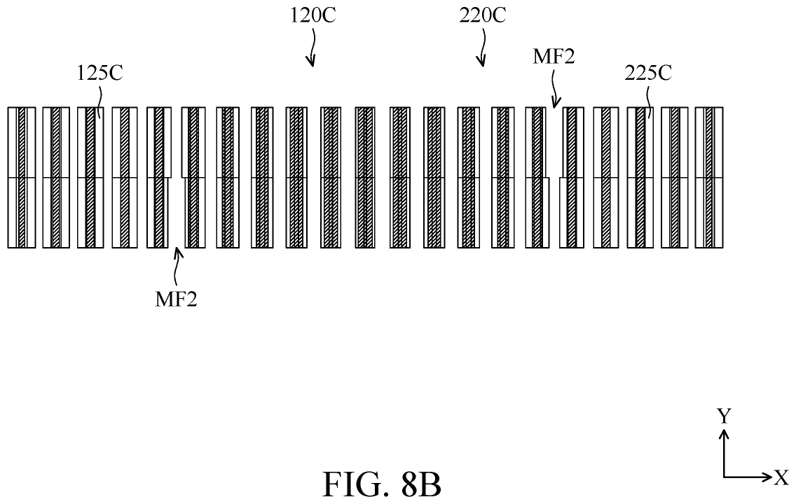

FIG. 8A-8B are schematic top views illustrating the first alignment mark 120 and the second alignment mark 220 in accordance with some embodiments of the present disclosure. As shown in FIG. 8A, the third sub-alignment mark 120C of the first alignment mark 120 is aligned with the third sub-alignment mark 220C of the second alignment mark 220. To be more specific, the standard pattern 125CC of the third sub-alignment mark 120C is substantially coincident with the standard pattern 220CC of the third sub-alignment mark 220C. In the top view (for example, shown in FIG. 8A), a corresponding pair of the first patterns 125C and the second pattern 225C may have a rectangular profile.

As shown in FIG. 8B, when the third sub-alignment mark 120C of the first alignment mark 120 is misaligned with the third sub-alignment mark 220C of the second alignment mark 220, a pair of misalignment features MF2 may be observed on opposite sides of the third sub-alignment mark 120C (and the third sub-alignment mark 220C). In particular, the misalignment features MF2 may be identified as an interference pattern formed by the optical signal passing through the varying spacing between the alignment marks 120 and 220 on the substrates 100 and 200. As a result, the misalignment error may be determined based on the location of the misalignment features MF2 and the pitch difference between the first patterns 125C and the second pattern 225C. For example, the resolution of the misalignment error may be about 10 nm, but the present disclosure is not limited thereto. To be more specific, the resolution of the misalignment error may be determined as the pitch difference between the pitch PC1 and the pitch PC2. In some embodiments, the resolution of the misalignment error may be in a range from about 1 nm to about 200 nm. Then, the misalignment error may be determined by the following formula:

The misalignment error=The resolution*The inversion point of light signal

In some embodiments, the inversion point of light signal may be identified as the two elongated patterns that are most aligned and have the widest spacing therebetween. Accordingly, the misalignment error may be obtained rapidly and the risk of miscalculating the misalignment error may be reduced.

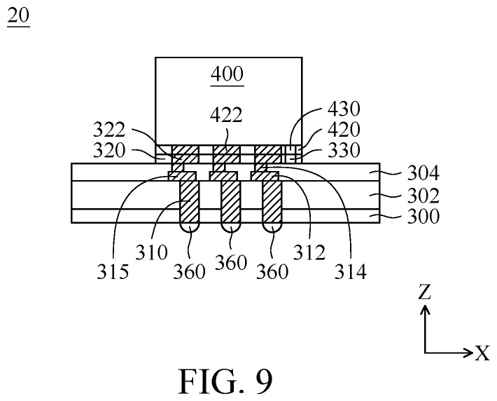

FIG. 9 is a cross-sectional view illustrating the package structure 20 in accordance with some embodiments of the present disclosure. For example, a first package component 300 includes a semiconductor substrate, including such as silicon, doped or undoped, or an active layer of a semiconductor-on-insulator (SOI) substrate. In some embodiments, the first package component 300 includes other semiconductor materials, such as germanium; a compound semiconductor including silicon carbide, gallium arsenic, gallium phosphide, indium phosphide, indium arsenide, and indium antimonide; an alloy semiconductor including SiGe, GaAsP, AlInAs, AlGaAs, GaInAs, GaInP, and GaInAsP; or a combination thereof. Other substrates, such as multi-layered or gradient substrates, may also be used.

In some embodiments, an interconnect structure 315 is formed in the first package component 300. In some embodiments, the interconnect structure 315 includes a plurality of through-silicon via (TSV) structures 310, a plurality of metallization patterns 312, and a plurality of conductive features 314. In some embodiments, the TSV structures 310 are formed in the first package component 300 and a dielectric layer 302 formed on the first package component 300. However, the present disclosure is not limited thereto. In some other embodiments, the dielectric layer 302 may be omitted, and the TSV structures 310 are completely located in the first package component 300.

In some embodiments, the dielectric layer 302 includes one or more sub-dielectric layers formed of materials such as silicon dioxide (SiO₂), Phospho-Silicate Glass (PSG), Boro-Silicate Glass (BSG), Boron-Doped Phospho-Silicate Glass (BPSG), undoped Silicate Glass (USG), or the like. In some embodiments, the dielectric layer 302 is formed, for example, by spin coating, lamination, chemical vapor deposition (CVD), or the like.

In some embodiments, the formation of the TSV structures 310 includes forming a plurality of trenches in the first package component 300. In some embodiments, the trenches extend into the first package component 300 and penetrate the dielectric layer 302 (if present) to electrically and physically couple the overlying metallization patterns 312. In some other embodiments, the TSV structures 310 may have a rectangular profile in the cross-sectional view. In some embodiments, the TSV structures 310 are formed of tungsten (W), cobalt (Co), nickel (Ni), copper (Cu), silver (Ag), gold (Au), aluminum (Al), any other suitable conductive material, or a combination thereof. However, the present disclosure is not limited thereto.

The metallization patterns 312 and the conductive features 314 are surrounded by a dielectric layer 304 for proper insulation, reducing the probability of forming short-circuit. In some embodiments, the dielectric layer 304 includes one or more sub-dielectric layers formed of materials such as silicon dioxide (SiO₂), Phospho-Silicate Glass (PSG), Boro-Silicate Glass (BSG), Boron-Doped Phospho-Silicate Glass (BPSG), undoped Silicate Glass (USG), or the like. In some embodiments, the dielectric layer 304 is formed, for example, by spin coating, lamination, chemical vapor deposition (CVD), or the like. In some embodiments, the dielectric layer 304 is formed by using material or method that is the same as that of the dielectric layer 302. However, the present disclosure is not limited thereto. In some embodiments, the dielectric layer 304 is formed by using material or method that is different from that of the dielectric layer 302.

In some embodiments, one or more devices (not individually shown) are in the formed in first package component 300 or the overlying dielectric layers 302, 304, and electrically connected to the TSV structures 310, the metallization patterns 312, and/or the conductive features 314. In some embodiments, the devices are active devices (e.g., transistors, diodes, etc.), capacitors, resistors, etc. For example, the devices are metal-oxide-semiconductor field-effect transistor (MOSFET), in accordance with some embodiments of the present disclosure.

In some embodiments, the metallization patterns 312 include metal lines and the conductive features 314 include vias formed in the dielectric layer 304. For example, the metallization patterns 312 and/or the conductive features 314 include conductive material such as tungsten (W), cobalt (Co), nickel (Ni), copper (Cu), silver (Ag), gold (Au), aluminum (Al), any other suitable conductive material, or a combination thereof. In some embodiments, the TSV structures 310, the metallization patterns 312, and/or the conductive features 314 are formed of the same material. In some other embodiments, the TSV structures 310, the metallization patterns 312, and/or the conductive features 314 are formed of different materials.

Accordingly, the TSV structures 310 is electrically connected to the metallization patterns 312 and the conductive features 314 for forming a conductive path connected to external environment (e.g. another semiconductor die or external devices). For example, when the devices in the first package component 300 are transistors, the TSV structures 310 may couple the gates or source/drain regions of the transistors. Source/drain regions may refer to a source or a drain, individually or collectively dependent upon the context.

In addition, a bonding film 320 is formed over the first package component 300 for the bonding process. For example, the material of the bonding film 320 includes SiON, SiO₂, any other suitable material, or a combination thereof. In some embodiments, a plurality of bonding pads 322 are formed in the bonding film 320. For example, the bonding pads 322 include conductive material such as tungsten (W), cobalt (Co), nickel (Ni), copper (Cu), silver (Ag), gold (Au), aluminum (Al), any other suitable conductive material, or a combination thereof. In some embodiments, the bonding pads 322 are formed corresponding to a second package component 400. However, the present disclosure is not limited thereto. In some embodiments, a first alignment mark 330 may be formed in the bonding film 320 and adjacent to the bonding pads 322. The first alignment mark 330 may be, for example, the second alignment mark 220, which includes one or more of the sub-alignment marks 220A-220D shown in the present disclosure. As set forth above, the sub-alignment marks 220A, 220B, 220C, and 220D may exist and function independently, as long as their corresponding sub-alignment marks 120A, 120B, 120C and 120D are present. However, all the possible alignment marks formed by the method shown in FIG. 1A-1D are contemplated within the scope of the present disclosure.

In some embodiments, a second package component 400 is bonded over the first package component 300. For example, the second package component 400 may be a device die, a package with a device die(s) packaged therein, a System-on-Chip (SoC) die including a plurality of device dies packaged as a system, or the like. The second package component 400 may be or may comprise logic dies, memory dies, input-output dies, Integrated Passive Devices (IPDs), or the like, or combinations thereof. For example, the logic device dies in the second package component 400 may be Central Processing Unit (CPU) dies, Graphic Processing Unit (GPU) dies, mobile application dies, Micro Control Unit (MCU) dies, BaseBand (BB) dies, Application processor (AP) dies, or the like. The memory dies in the second package component 400 may include Static Random Access Memory (SRAM) dies, Dynamic Random Access Memory (DRAM) dies, or the like. The second package component 400 may include semiconductor substrates and interconnect structures, which are not individually shown in the present embodiment.

In addition, another bonding film 420 is formed on the second package component 400 for the bonding process. For example, the material of the bonding film 420 includes SiON, SiO₂, any other suitable material, or a combination thereof. In some embodiments, the material of the bonding film 420 is the same as the material of the bonding film 320. Although two bonding films (e.g. the bonding film 320 and the bonding film 420) are shown in the present disclosure, it should be appreciated that one or multiple (more than two) bonding films are also adopted in the present disclosure.

In some embodiments, a plurality of bonding pads 422 are formed in the bonding film 420. For example, the bonding pads 422 include conductive material such as tungsten (W), cobalt (Co), nickel (Ni), copper (Cu), silver (Ag), gold (Au), aluminum (Al), any other suitable conductive material, or a combination thereof. In some embodiments, the bonding pads 422 are each aligned with the bonding pads 322 over the first package component 300 to form electrical connection between the second package component 400 and the interconnect structure 315. In some embodiments, a second alignment mark 430 may be formed in the bonding film 420 and adjacent to the bonding pads 422. The second alignment mark 430 may be, for example, the first alignment mark 120, which includes one or more of the sub-alignment marks 120A-120D shown in the present disclosure. As set forth above, the sub-alignment marks 120A, 120B, 120C, and 120D may exist and function independently, as long as their corresponding sub-alignment marks 220A, 220B, 220C and 220D are present. However, all the possible alignment marks formed by the method shown in FIG. 1A-1D are contemplated within the scope of the present disclosure. In some embodiments, the second alignment mark 430 is aligned with the first alignment mark 330 to facilitate the bonding process.

In some embodiments, a plurality of bump structures 360 are formed on the exposed TSV structures 310. That is, the bump structures 360 are formed on the first package component 300 and cover the exposed surfaces of the TSV structures 310. In some embodiments, the bump structures 360 may include controlled collapse chip connection (C4) bumps, solder bumps, copper bumps, micro bumps, electroless nickel-electroless palladium-immersion gold technique (ENEPIG) formed bumps, ball grid array (BGA) bumps, copper pillars, or the like.

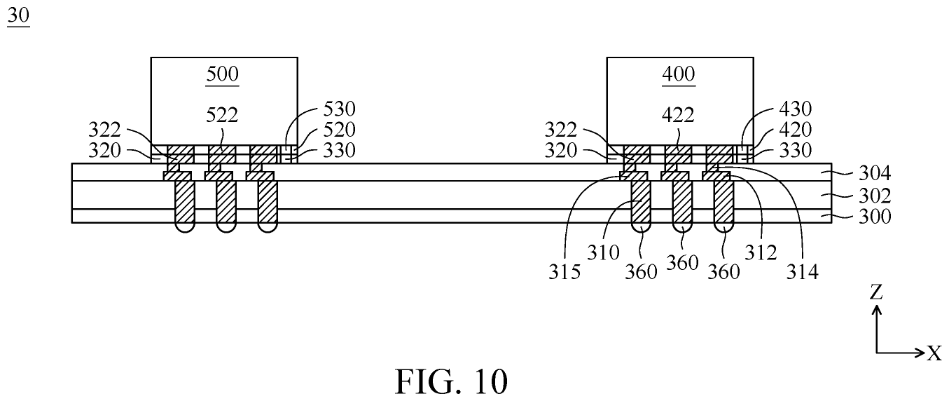

FIG. 10 is a cross-sectional view illustrating the package structure 30 in accordance with some embodiments of the present disclosure. It should be noted that the package structure 30 in the present embodiment may include elements that are the same or similar to the package structure 20 shown in FIG. 9. These elements are denoted by the same or similar numerals and will not be discussed in detail in the following paragraphs. As shown in FIG. 10, the package structure 30 includes a first package component 300, an interconnect structure 315 in the first package component 300, and a second package component 400. The second package component 400 is bonded over the first package component 300 via multiple bonding films 320 and 340.

In some embodiments, a third package component 500 is bonded over the first package component 300. For example, the third package component 500 may be a device die, a package with a device die(s) packaged therein, a System-on-Chip (SoC) die including a plurality of device dies packaged as a system, or the like. The third package component 500 may be or may comprise logic dies, memory dies, input-output dies, Integrated Passive Devices (IPDs), or the like, or combinations thereof. For example, the logic device dies in the third package component 500 may be Central Processing Unit (CPU) dies, Graphic Processing Unit (GPU) dies, mobile application dies, Micro Control Unit (MCU) dies, BaseBand (BB) dies, Application processor (AP) dies, or the like. The memory dies in the third package component 500 may include Static Random Access Memory (SRAM) dies, Dynamic Random Access Memory (DRAM) dies, or the like. The third package component 500 may include semiconductor substrates and interconnect structures, which are not individually shown in the present embodiment.

In addition, another bonding film 520 is formed on the third package component 500 for the bonding process. For example, the material of the bonding film 520 includes SiON, SiO₂, any other suitable material, or a combination thereof. In some embodiments, the material of the bonding film 520 is the same as the material of the bonding film 320. Although two bonding films (e.g. the bonding film 320 and the bonding film 520) are shown in the present disclosure, it should be appreciated that one or multiple (more than two) bonding films are also adopted in the present disclosure.

In some embodiments, a plurality of bonding pads 522 are formed in the bonding film 520. For example, the bonding pads 522 include conductive material such as tungsten (W), cobalt (Co), nickel (Ni), copper (Cu), silver (Ag), gold (Au), aluminum (Al), any other suitable conductive material, or a combination thereof. In some embodiments, the bonding pads 522 are each aligned with the bonding pads 322 over the first package component 300 to form electrical connection between the third package component 500 and the interconnect structure 315.

In some embodiments, a third alignment mark 530 may be formed in the bonding film 520 and adjacent to the bonding pads 522. The third alignment mark 530 may be, for example, the first alignment mark 120, which includes one or more of the sub-alignment marks 120A-120D shown in the present disclosure. As set forth above, the sub-alignment marks 120A, 120B, 120C, and 120D may exist and function independently, as long as their corresponding sub-alignment marks 220A, 220B, 220C and 220D are present. However, all the possible alignment marks formed by the method shown in FIG. 1A-1D are contemplated within the scope of the present disclosure. In some embodiments, the third alignment mark 530 is aligned with the first alignment mark 330 to facilitate the bonding process. In some embodiments, the third alignment mark 530 is different from the second alignment mark 430 to reduce the risk that the third package component 500 and/or the second package component 400 is mounted on wrong positions.

As described above, the present disclosure is directed to package structures and methods for forming the same. The package structure includes a first alignment mark and a second alignment mark corresponding to each other. Each of the first alignment mark and the second alignment mark includes a first group and a second group extending in two directions. Accordingly, the two-dimensional (2D) alignment may be achieved. In addition, a plurality of overlapped sub-alignment marks are provided in the first alignment mark and the second alignment mark, and therefore different resolution of alignment error during the assembly of package structure may be obtained. By means of arranging multiple sub-alignment marks, the alignment error may be double-checked.

In accordance with some embodiments, a package structure is provided and includes a first bonding film on a first package component, and a first alignment mark in the first bonding film. The first alignment mark includes a plurality of first patterns spaced apart from each other. The package structure includes a second bonding film on a second package component and bonded to the first bonding film, and a second alignment mark in the second bonding film. The second alignment mark includes a plurality of second patterns spaced apart from each other, and the first patterns overlap the second patterns. In a top view, each of the first patterns is divided into a first portion and a second portion, the first portions of the first patterns are separated by a first pitch, the second portions of the first patterns are separated by a second pitch, and the first pitch is different from the second pitch.

In accordance with some embodiments, a method of forming a package structure is provided and includes forming a first bonding film on a first package component. The method includes forming a first alignment mark in the first bonding film. The first alignment mark includes a plurality of first patterns spaced apart from each other. The method includes forming a second bonding film on a second package component. The method includes forming a second alignment mark in the second bonding film. The second alignment mark includes a plurality of second patterns spaced apart from each other. The method includes moving either the first package component or the second package component to align the first alignment mark with the second alignment mark. The method includes determining if the first alignment mark is aligned with the second alignment mark by determining whether the edges of the standard pattern of the first patterns coincide with the edges of the standard pattern of the second patterns. After determining that the first alignment mark is aligned with the second alignment mark the method includes bonding the second package component to the first package component.

In accordance with some embodiments, a package structure is provided and includes a first bonding film and a second bonding film. The first bonding film is on a first package component, wherein a first alignment mark is formed in the first bonding film and includes a plurality of first patterns spaced apart from each other by a first pitch. The second bonding film is on a second package component and bonded to the first bonding film, wherein a second alignment mark is formed in the second bonding film and includes a plurality of second patterns spaced apart from each other by a second pitch. The second package component is bonded to the first package component via the first bonding film and the second bonding film, and the first pitch is different from the second pitch.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package structure, comprising:
a first bonding film formed on a first package component;
a first alignment mark formed in the first bonding film, wherein the first alignment mark comprises a plurality of first patterns spaced apart from each other;
a second bonding film formed on a second package component and bonded to the first bonding film; and
a second alignment mark formed in the second bonding film, wherein the second alignment mark comprises a plurality of second patterns spaced apart from each other, and the first patterns overlap the second patterns,
wherein in a top view, each of the first patterns is divided into a first portion and a second portion, the first portions of the first patterns are separated by a first pitch, the second portions of the first patterns are separated by a second pitch, and the first pitch is different from the second pitch.

2. The package structure as claimed in claim 1, wherein a first group of the first patterns are arranged in a first direction, and a second group of the first patterns are arranged in a second direction perpendicular to the first direction.

3. The package structure as claimed in claim 2, wherein in the top view, the first group of the first patterns are arranged symmetrically about a central axis.

4. The package structure as claimed in claim 2, wherein in the top view, each of the second patterns is divided into a first portion and a second portion, the first portions of the second patterns overlap the first portions of the first patterns and are separated by the second pitch.

5. The package structure as claimed in claim 4, wherein the second portions of the second patterns overlap the second portions of the first patterns and are separated by the first pitch.

6. The package structure as claimed in claim 1, wherein in the top view, the first portions and the second portions of the first patterns each have an elongated shape.

7. The package structure as claimed in claim 1, wherein each of the first patterns comprises:
a dielectric layer provided within the first bonding film; and
a metal layer provided within the first bonding film so that the dielectric layer is disposed between the metal layer and the bonding film, wherein a top surface of the metal layer is substantially level with a top surface of the first bonding film.

8. A method of forming a package structure, comprising:
forming a first bonding film on a first package component;
forming a first alignment mark in the first bonding film, wherein the first alignment mark comprises a plurality of first patterns spaced apart from each other;
forming a second bonding film on a second package component;
forming a second alignment mark in the second bonding film, wherein the second alignment mark comprises a plurality of second patterns spaced apart from each other;
moving either the first package component or the second package component to align the first alignment mark with the second alignment mark;
determining if the first alignment mark is aligned with the second alignment mark by determining whether edges of a standard pattern of the first patterns coincide with edges of a standard pattern of the second patterns; and
after determining that the first alignment mark is aligned with the second alignment mark, bonding the second package component to the first package component.

9. The method as claimed in claim 8, wherein forming the first alignment mark comprises symmetrically arranging the first patterns on opposite sides of the standard pattern.

10. The method as claimed in claim 8, wherein forming the first alignment mark comprises:
providing first portions of the first patterns separated by a first pitch in a top view; and
providing second portions of the first patterns separated by a second pitch in the top view, wherein the first pitch is different from the second pitch.

11. The method as claimed in claim 8, wherein a length of the standard pattern of the first patterns is different from a length of the standard pattern of the second patterns in a direction parallel to the edges of the standard pattern of the first patterns.

12. The method as claimed in claim 11, wherein the first patterns are identical to each other.

13. The method as claimed in claim 11, wherein one of the second patterns comprises a first portion and a second portion spaced apart from the first portion.

14. A package structure, comprising:
a first bonding film on a first package component, wherein a first alignment mark is formed in the first bonding film and comprises a plurality of first patterns spaced apart from each other by a first pitch; and
a second bonding film on a second package component and bonded to the first bonding film, wherein a second alignment mark is formed in the second bonding film and comprises a plurality of second patterns spaced apart from each other by a second pitch,
wherein the second package component is bonded to the first package component via the first bonding film and the second bonding film, and the first pitch is different from the second pitch.

15. The package structure as claimed in claim 14, wherein the first patterns have a shape of a rectangle with a uniform length.

16. The package structure as claimed in claim 14, wherein one of the second patterns comprises a first portion and a second portion spaced apart from the first portion.

17. The package structure as claimed in claim 14, wherein in a top view, one of the second patterns is partially exposed from one of the first patterns overlapping the one of the second patterns.

18. The package structure as claimed in claim 14, further comprising:
a third bonding film on a third package component, wherein a third alignment mark is formed in the third bonding film and comprises a plurality of third patterns,
wherein the third package component is bonded to the first package component via the first bonding film and the third bonding film.

19. The package structure as claimed in claim 18, wherein a profile of the third patterns is different from a profile of the second patterns.

20. The package structure as claimed in claim 14, wherein the first patterns are symmetrically arranged about a first axis, the second patterns are symmetrically arranged about a second axis, and the first axis is parallel to the second axis.
